(19) United States
(12) Patent Application Publication
(10) Pub. No.: US 2008/0258043 A1
(43) Pub. Date: Oct. 23, 2008

(54) Optical element and optical equipment

(76) Inventors: Koji Suzuki, Sagamihara-shi (JP); Ken Kawamata, Tachikawa-shi (JP)

Correspondence Address: KENYON & KENYON LLP, ONE BROADWAY, NEW YORK, NY, 10004, US

(21) Appl. No.: 11/787,853

(22) Filed: Apr. 17, 2007

(51) Int. Cl. H01L 27/00

(52) U.S. Cl. 250/208.1; 250/226

(57) ABSTRACT

The optical element includes a substrate and optical thin film formed in multiple layers on the surface of the pertinent substrate, wherein the optical thin film is provided with low refractive index layers composed of material with a lower refractive index than that of the substrate, and high refractive index layers of which at least 1 layer is composed of material whose primary component is oxide and which have a refractive index higher than that of the low refractive index layers, and wherein at least 1 layer of the optical thin film composed of low refractive index layers and high refractive index layers contains at least one of metal ions selected from among Cu, Fe, Au, Ag, Cr, Mn, Co, and Ni.

### BACKGROUND OF THE INVENTION

1. Field of the Invention

The present invention relates to an optical element wherein optical thin film which absorbs light is formed on a substrate, and to optical equipment provided therewith.

2. Description of Related Art

Solid-state image sensors such as CCDs (charge-coupled devices) built into optical equipment such as digital cameras, microscopes, endoscopes and the like are silicon semiconductor devices which convert light (images) into electric signals. As these solid-state image sensors are sensitive to infrared rays (IR), near-infrared rays which are invisible at optical wavelengths are also captured as images. Consequently, in order that only the light (images) at visible optical wavelengths taken into lens group is converted to electric signals in the CCD, a near-infrared-ray cut-off filter is interposed between the CCD and the lens group. The transmittance spectrum of this IR cut-off filter constitute an important factor when determining the color reproducibility of the images obtained with interposition of a CCD such as a digital camera.

As types of IR cut-off filters, there is the glass type where IR is cut off by components in the glass using optical absorption, and the coating type where IR is cut off by reflection using the interference of light. Furthermore, IR cut-off filters (light ray cut-off filter) making combined use of both the glass type and coating type have been offered (e.g., see Japanese Unexamined Patent Application, First Publication No. 2003-161831).

First, with respect to the glass type IR cut-off filter, glass containing copper ions or the like is used, and these metal ions fused into the glass absorb infrared rays (the unnecessary light) while allowing transmission of visible light (the necessary light). Moreover, with the glass type IR cut-off filters, there is hardly any influence on transmittance spectrum relative to the angle of incidence of light. Furthermore, the glass type IR cut-off filter can facilitate simplification of the configuration of optical equipment such as digital cameras by bonding with a quartz birefringent plate to endow it with the function of an optical low-pass filter.

On the other hand, IR cut-off filter coatings use optical thin film wherein materials with a high refractive index such as TiO₂, Ta₂O₅ and Nb₂O₅ and materials with a low refractive index such as SiO₂ and MgF₂ are alternately formed as film on an optical low-pass filter using a birefringent plate of quartz or lithium niobate as the substrate material by the commonly employed vacuum deposition method, spattering method or the like. By means of such optical thin film, infrared rays (the unnecessary light) are reflected using the interference of light, while visible light (the necessary light) is transmitted.

In the case where the glass type and coating type of IR cut-off filter are used in tandem, it is possible to transmit visible light and cut off near-infrared rays. That is, as the transmittance spectrum of the IR cut-off filter exhibit “the characteristic of gradual decline in transmittance from the visible light region to the near-infrared region,” they desirably approximate the sensitivity behavior of the human eye.

### SUMMARY OF THE INVENTION

The present invention offers the following means.

The optical element of the present invention is an optical element which includes a substrate and optical thin film formed in multiple layers on the surface of the pertinent substrate, wherein said optical thin film is provided with low refractive index layers composed of material with a lower refractive index than that of said substrate, and high refractive index layers of which at least 1 layer is composed of material whose primary component is oxide and which have a refractive index higher than that of said low refractive index layers, and wherein at least 1 layer of said optical thin film composed of said low refractive index layers and said high refractive index layers contains at least one of metal ions selected from among Cu, Fe, Au, Ag, Cr, Mn, Co, and Ni.

Additionally, the optical element of the present invention is an optical element having a substrate and optical thin film formed on the surface of the pertinent substrate, wherein said optical thin film is provided with a first layer composed of material whose main component is SiO₂ or MgF₂, and a second layer composed of Cu, O and at least one of Ta, Nb, Ti, W, Zr, Hf, Ce, La and Bi, and wherein the first layer is the layer formed at the position which is farthest away from said substrate among the layers configuring said optical thin film.

Additionally, with the optical element of the present invention, it is preferable that said optical thin film be a near-infrared ray cut-off filter which causes visible light to be transmitted, which absorbs a portion of the near-infrared rays, and which reflects near-infrared rays other than said absorbed near-infrared rays.

Additionally, with the optical element of the present invention, it is preferable that said optical thin film possess transmittance having the function of an ultraviolet ray cut-off filter which absorbs a portion of the ultraviolet rays and which reflects ultraviolet rays other than said absorbed ultraviolet rays.

Additionally, with the optical element of the present invention, it is preferable that said optical thin film be provided at the first layer of said optical thin film from said substrate side with an equal refractive index layer which has a refractive index approximately equal to that of said substrate, and that said equal refractive index layer contains at least one of metal ions selected from among Cu, Fe, Au, Ag, Cr, Mn, Co, and Ni.

Additionally, with the optical element of the present invention, it is preferable that said substrate is quartz.

Additionally, the optical equipment of the present invention is preferably provided with the aforementioned optical element.

### BRIEF DESCRIPTION OF THE DRAWINGS

FIG. 1 is a sectional view showing an optical thin-film deposition system pertaining to a first embodiment of the present invention.

FIG. 2 is a planar view showing an optical element pertaining to the first embodiment of the present invention.

FIG. 3 shows designed standard film thickness values of optical thin film of the optical element of FIG. 2.

FIG. 4 shows transmittance spectrum of antireflection film of the optical element of FIG. 2.

FIG. 5 shows transmittance spectrum of Ta₂O₅ film for the case where the optical element pertaining to the first embodiment of the present invention contains Cu and for the case where it does not.

FIG. 6 shows transmittance spectrum of SiO₂ film for the case where the optical element pertaining to the first embodiment of the present invention contains Cu and for the case where it does not.

FIG. 7 shows transmittance spectrum for the case where the optical element pertaining to the first embodiment of the present invention contains Cu and for the case where it does not.

FIG. 8 shows transmittance spectrum according to variations in the angle of incidence of the optical element pertaining to the first embodiment of the present invention.

FIG. 9 shows transmittance spectrum of Ta₂O₅ film for the case where the optical element pertaining to a second embodiment of the present invention contains Cu and for the case where it does not.

FIG. 10 shows transmittance spectrum of SiO₂ film for the case where the optical element pertaining to the second embodiment of the present invention contains Cu and for the case where it does not.

FIG. 11 shows transmittance spectrum for the case where the optical element pertaining to the second embodiment of the present invention contains Cu and for the case where it does not.

FIG. 12 is a planar view of optical equipment pertaining to a third embodiment of the present invention.

FIG. 13 shows transmittance spectrum according to variations in the angle of incidence of the optical element of a conventional example.

FIG. 14A is a view showing the optical element pertaining to a fourth embodiment of the present invention, and is a planar view showing the state where a first layer is disposed on one face of the quartz substrate.

FIG. 14B is a view showing the optical element pertaining to the fourth embodiment of the present invention, and is a planar view showing the state where optical thin film which is a near-infrared ray cut-off filter is disposed on the first layer.

FIG. 14C is a view showing the optical element pertaining to the fourth embodiment of the present invention, and is a planar view showing the state where optical thin film which is a near-infrared ray cut-off filter is disposed on the first layer, and where optical thin film which is an ultraviolet ray cut-off filter is disposed on the other face of the quartz substrate.

FIG. 15 shows designed standard film thickness values of optical thin film which are disposed on one face of the substrate of FIG. 14A-C.

FIG. 16 shows designed standard film thickness values of optical thin film which are disposed on the other face of the substrate of FIG. 14A-C.

FIG. 17 shows transmittance spectrum for the case where the optical element of FIG. 14A contains Fe and for the case where it does not.

FIG. 18 shows transmittance spectrum of the optical element of FIG. 14B.

FIG. 19 shows transmittance spectrum of the optical element of FIG. 14C.

### DESCRIPTION OF THE PREFERRED EMBODIMENTS

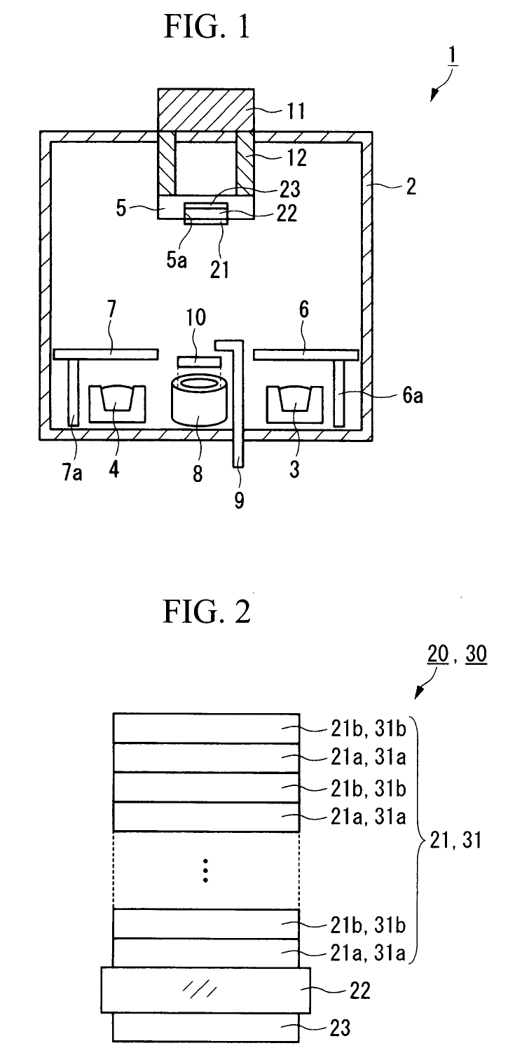

The first embodiment of the present invention is described with reference to FIG. 1 to FIG. 8.

With respect to an optical element 20 pertaining to the present embodiment, optical thin film is formed by an optical thin-film deposition system 1 like that shown in FIG. 1.

As shown in FIG. 1 and FIG. 2, this optical thin-film deposition system 1 is a device which forms optical thin film 21 on a substrate 22 which becomes a product and disposed inside a vacuum chamber 2. The optical thin-film deposition system 1 is provided with two vapor deposition sources 3 and 4, a substrate holder 5, shutters 6 and 7, property measurement means (not illustrated), film thickness control system (not illustrated), ion gun 8, and gas induction tube 9. The two vapor deposition sources 3 and 4 are arranged opposite the substrate 22 at the bottom side of the vacuum chamber 2, and at positions which are deviated from the central axis. The substrate holder 5 holds the single substrate 22 in place at an approximately central position at the upper side of the vacuum chamber 2, and faces opposite the vapor deposition sources 3 and 4 in a slanted manner. The shutters 6 and 7 are respectively arranged directly above the vapor deposition sources 3 and 4, and are capable of serving as shields between the vapor deposition sources 3 and 4 and the substrate holder 5. The property measurement means measures optical property values of the optical thin film 21 formed on the substrate 22. The film thickness control system conducts thickness control of the film. The ion gun 8 is placed between the vapor deposition sources 3 and 4 and oriented toward the substrate 22 on which the optical thin film 21 is formed; and the ion gun 8 injects metal elements into the optical thin film 21 on this substrate 22. The gas induction tube 9 is capable of introducing gas above the ion gun 8 between the ion gun 8 and the optical thin film 21 formed on the substrate 22 during injection of the metal elements.

Moreover, the substrate 22 uses S-BSL7 glass manufactured by OHARA, and this substrate 22 is held in the substrate holder 5 so that the 5-layer antireflection film 23 which is pre-formed relative to the pertinent substrate 22 is positioned at the upper side of the vacuum chamber 2. Additionally, for purposes of injecting the metal elements, a plate 10 composed of Cu is arranged between the ion gun 8 and gas induction tube 9.

The shutters 6 and 7 are respectively supported by shutter support rods 6a and 7a. By moving the shutters 6 and 7 between positions directly above the vapor deposition sources 3 and 4 and positions off from there, film deposition commencement and termination of each layer is conducted on the substrate 22 by means of evaporated material from the vapor deposition sources 3 and 4, and film thickness control of each layer is conducted.

The vapor deposition source 3 uses Ta₂O₅ as high refractive index material, while the vapor deposition source 4 uses SiO₂ as low refractive index material.

The substrate holder 5 is supported so as to be capable of rotating at an approximately central position of the vacuum chamber 2 by a drive motor 11 arranged atop the vacuum chamber 2 and a drive transmission means (gear) not shown in figures which is coupled with this drive motor 11, with interposition of a hollow support shaft 12 which extends inside the vacuum chamber 2.

An aperture 5a is provided in the substrate holder 5, and runs vertically through it. A single substrate 22 is held in this aperture 5a.

The substrate holder 5 is configured to hold only a single substrate 22 for film deposition, but it is not limited to a substrate holder 5 which holds only a single substrate 22. For example, it is also acceptable to configure the substrate holder 5 in a hemispherical form, planar form, stepped hemispherical form, or autonomously revolving form having multiple flat plates or hemispherical molds so as to hold multiple substrates 22. Additionally, a heater (not illustrated) for heating the substrate holder 5 and substrate 22 may also be incorporated into the vacuum chamber 2.

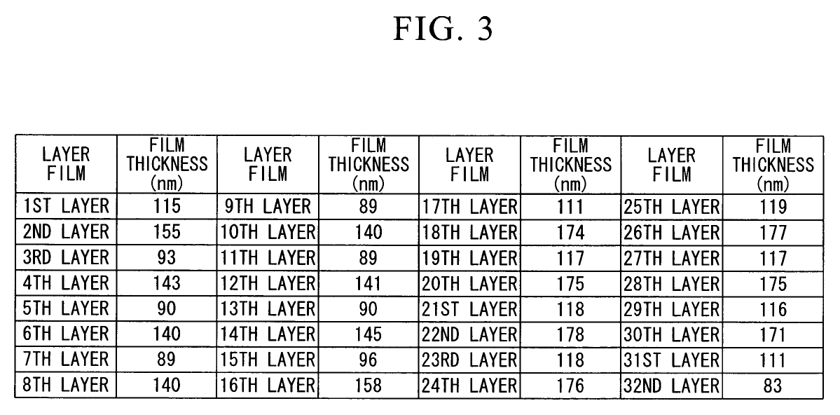

Next, a description is given of the method of forming the thin film which is formed from high refractive index layers and low refractive index layers as shown in FIG. 2 using the optical thin-film deposition system 1 of the present embodiment configured in the foregoing manner. Here, the high refractive index layers are formed from a substance made of a high refractive index oxide material 21a which is composed of Ta₂O₅ containing approximately 2% of Cu. The low refractive index layers are formed from a substance made of a low refractive index oxide material 21b which is composed of SiO₂ containing approximately 2% of Cu. Based on the designed standard film thickness as shown in FIG. 3, a multilayer optical thin film is formed by alternately laminating 32 layers.

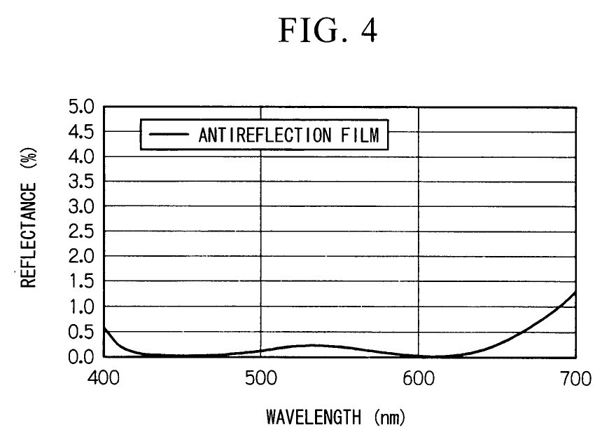

First, as shown in FIG. 2, a 5-layer antireflection film 23 is formed on one face of the substrate 22 by the vacuum deposition method using the optical thin-film deposition system (not illustrate) while maintaining the temperature of the substrate 22 at 300° C. At this time, an antireflection film 23 is formed on the substrate 22 such that the reflectance spectrum of the antireflection film 23 exhibit a reflectance of 0.7% or less at a wavelength of 400 nm to 670 nm and a reflectance of 1.5% or less at a wavelength of 671 nm to 700 nm on one face of the substrate 22, as shown in FIG. 4.

Next, a description is given for the case where the optical thin film 21 is formed by alternately laminating 32 layers of Ta₂O₅ film and SiO₂ film on the face of the substrate 22 which is opposite the face on which the antireflection film is formed. This laminated optical thin film 21 is used as an optical filter.

First, the substrate 22 is attached to the aperture 5a of the substrate holder 5 so that the face of the substrate 22 which is opposite the face on which the formed antireflection film 23 is provided facing the bottom side of the vacuum chamber 2. Next, the drive motor 11 is driven, and the substrate 22 supported by the support shaft 12 is rotated. The film deposition process which forms the optical thin film 21 on the substrate 22 is then conducted while maintaining the temperature of the substrate 22 at 200° C. by heating the substrate holder 5 with a heater.

In this film deposition process, first, the tops of the vapor deposition sources 3 and 4 are covered by the shutters 6 and 7, and preparations for film deposition by the vapor deposition method are conducted. At the point when pressure inside the vacuum chamber 2 reaches to 1×10⁻³ Pa, the shutter 6 which had been covering the top of vapor deposition source 3 is moved away from the top of vapor deposition source 3. By this means, formation of optical thin film of high refractive index oxide material 21a composed of the vapor deposited substance Ta₂O₅ which is set as vapor deposition source 3 commences on the substrate 22. At this time, O₂ gas is introduced from the gas induction tube 9, pressure is set to 2.5×10⁻² Pa, and an Ar ion beam from the ion gun 8 irradiates for a specified time the high refractive index oxide material 21a being formed on the substrate 22. By this means, the plate 10 arranged above the ion gun 8 is etched, and film deposition proceeds while Cu metal oxide is taken into the high refractive index oxide material 21a. Subsequently, at the point when Ta₂O₅ film thickness reaches the designed standard film thickness of 115 nm, the shutter 6 is moved to the position above vapor deposition source 3 to cover it, and film deposition of the first layer terminates. Here, the ratio at which Cu is taken in is primarily dependent on the vapor deposition rate and ion gun power, and, in this instance, film deposition is conducted such that these are respectively 3 Å/sec and 600 W, resulting in Cu content of approximately 2%.

Next, the shutter 7 which had been covering the top of vapor deposition source 4 is moved away from the top of vapor deposition source 4, and formation of optical thin film of low refractive index oxide material 21b composed of the vapor deposited substance SiO₂ which is set as vapor deposition source 4 commences on the first layer (Ta₂O₅ film) of the substrate 22. At this time, O₂ gas is introduced from the gas induction tube 9, pressure is set to 2.0×10⁻² Pa, and an Ar ion beam from the ion gun 8 irradiates for a specified time the low refractive index oxide material 21b being formed on the substrate 22. By this means, the plate 10 arranged above the ion gun 8 is etched, and film deposition proceeds while Cu metal oxide is taken into the low refractive index oxide material 21b. Subsequently, at the point when SiO₂ film thickness reaches the designed standard film thickness of 155 nm, the shutter 7 is moved to the position above vapor deposition source 4 to cover it, and film deposition of the second layer terminates. Here, the ratio at which Cu is taken in is primarily dependent on the vapor deposition rate and ion gun power, and, in this instance, film deposition is conducted such that these are respectively 7 Å/sec and 600 W, resulting in Cu content of approximately 2%.

Furthermore, by repeatedly conducting film deposition by the aforementioned film deposition process so as to reach the designed standard film thickness of each layer such as those shown in FIG. 3, the multilayer optical thin film 21 laminated in 32 layers is obtained.

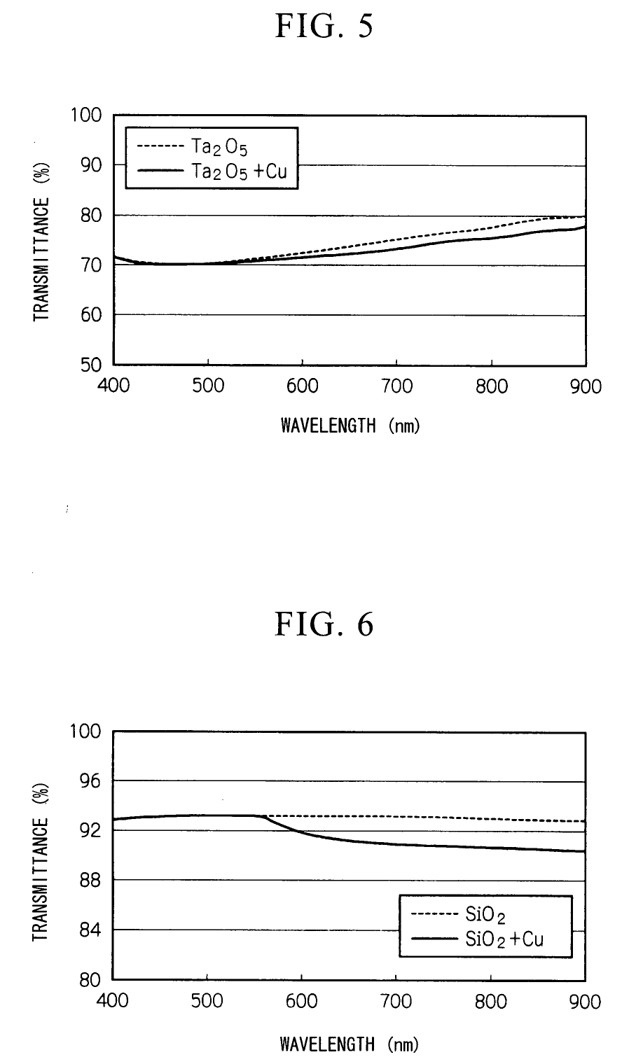

Here, as a comparison with this first embodiment, a spectrophotometer (U-4000, manufactured by Hitachi, Ltd.) was used to measure transmittance spectrum at wavelengths from 400 nm to 900 nm when a Ta₂O₅ monolayer refractive index layer was formed at λ/4 (λ=500 nm) in the cases where there was Cu content of approximately 2% on the substrate 22 and where there was no Cu content, and the results are shown in FIG. 5. As is clear from this figure, as a result of Cu absorption on the long wavelength side from the vicinity of 550 nm, compared to the case where λ/4 film deposition is conducted without Cu content, it is possible to obtain optical properties with the Ta₂O₅ monolayer refractive index layer containing Cu metal ions such that transmittance is attenuated by 1% at 600 nm and by 2% at 700 nm

Furthermore, as a comparison with this first embodiment, a U-4000 spectrophotometer (manufactured by Hitachi, Ltd.) was used to measure transmittance spectrum at wavelengths from 400 nm to 900 nm when a SiO₂ monolayer refractive index layer was formed at λ/4 (λ=500 nm) in the cases where there was Cu content of approximately 2% on the substrate 22 and where there was no Cu content, and the results are shown in FIG. 6. As is clear from this Figure, as a result of Cu absorption on the long wavelength side from the vicinity of 550 nm, compared to the case where λ/4 film deposition is conducted without Cu content, it is possible to obtain optical properties with the SiO₂ monolayer refractive index layer containing Cu metal ions such that transmittance is attenuated by 1.5% at 600 nm and by 3% at 700 nm.

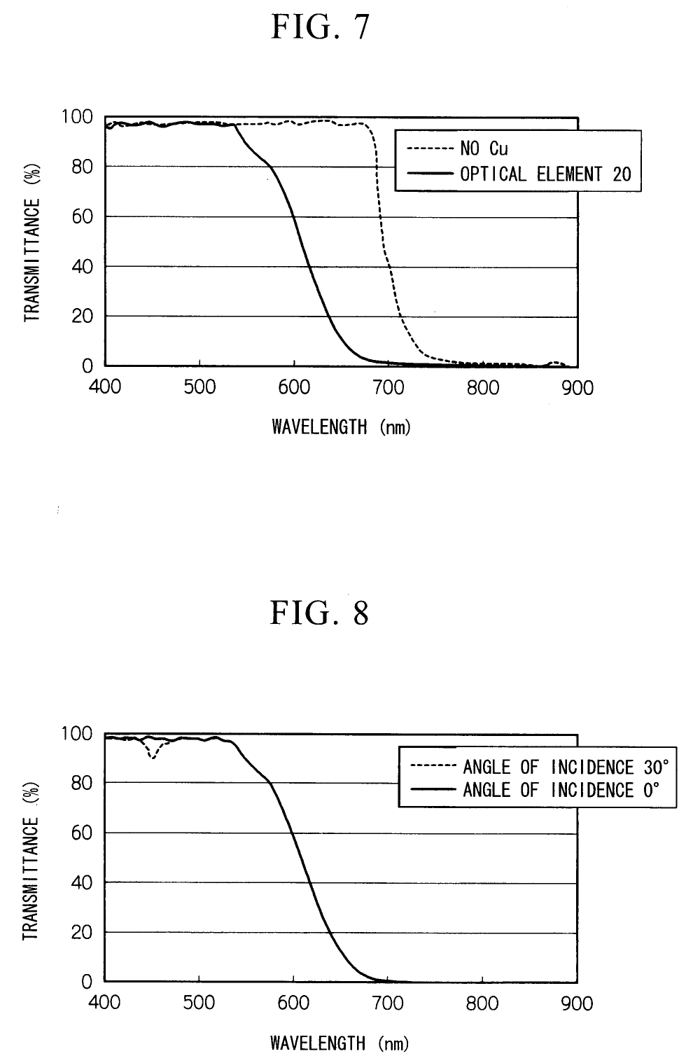

Additionally, the transmittance spectrum of the optical element 20 formed by the present embodiment at wavelengths was measured by a U-4000 spectrophotometer (manufactured by Hitachi, Ltd.) at wavelengths from 400 nm to 900 nm, and the results are shown in FIG. 7. When the optical element formed by Ta₂O₅ and SiO₂ without Cu content is compared with the optical element 20 which forms 32 layers of film such that film thicknesses like those shown in FIG. 3 are reached, this optical element 20 obtains transmittance that gradually attenuates from 550 nm to 700 nm as a result of the absorption of Cu metal ions on the long wavelength side from the vicinity of 550 nm. Specifically, it is possible to obtain an optical element 20 possessing transmittance of 58% at 600 nm and 0.5% at 700 nm.

Furthermore, the wavelength properties of transmittance were measured by a U-4000 spectrophotometer (manufactured by Hitachi, Ltd.) when the angle of incidence of the optical element 20 was 0 degrees and when the angle of incidence was 30 degrees at wavelengths of 400 nm to 900 nm, and the results are shown in FIG. 8. As is clear from this figure, there is hardly any change in the gradually attenuating transmittance from 550 nm to 700 nm when the angle of incidence is 0 degrees and when the angle of incidence is 30 degrees. Additionally, while a certain amount of rippling of transmittance occurs in the vicinity of 450 nm, it is possible to obtain transmittance spectrum which scarcely varies relative to the angle of incidence.

According to the optical element 20 of the present embodiment, by utilizing the characteristic of light absorption of the metal element Cu contained in the optical thin film 21 formed on the substrate 22, it is possible to cause transmission of necessary light such as visible light, and to absorb unnecessary light such as infrared rays. Additionally, according to this invention, it is possible to suppress the influence sustained by transmittance spectrum when changes occur in the angle of incidence, and one can obtain an optical element constituting an infrared ray cut-off filter of the coating type alone wherein optical properties such as transmittance spectrum are not dependent on the angle of incidence of light. Furthermore, it is possible to obtain an optical element which has the characteristic that transmittance gently declines from the visible region to the near-infrared region in an approximation of the sensitivity behavior of the human eye that is considered to have the most preferable transmittance, and which constitutes an infrared ray cut-off filter that absorbs and cuts off near-infrared rays.

Additionally, by laminating high refractive index oxide material 21a and low refractive oxide material 21b, it is possible to cut off unnecessary light not only by the light absorption of metal, but also by reflection utilizing the light interference of the optical thin film, and to expand the non-transmission band.

Next, a description is given of the second embodiment pertaining to the present invention with reference to FIG. 2 and FIG. 9 to FIG. 11. In each of the embodiments explained below, the same reference numbers are given to parts that are common to the configuration of the optical thin-film deposition system 1 and the optical element 20 pertaining to the above-described first embodiment, and description thereof is omitted.

The optical thin-film deposition system which forms the optical element 30 of the present embodiment differs from the first embodiment in two points. With respect to the first point, in the second embodiment, the plate 10 provided between the ion gun 8 and gas induction tube 9 enabling gas induction uses material of the metal element Fe, rather than material of the metal element Cu. With respect to the second point, the second embodiment uses material composed of high refractive index oxide material (the high refractive index layer) 31a and low refractive index oxide material (the low refractive index layer) 31b both with Fe content of approximately 2%, as shown in FIG. 2, rather than the high refractive index oxide material 21a and low refractive index oxide material 21b containing Cu metal ions.

Next, a description is given of the method of forming thin film formed by a first layer and a second layer using the optical thin-film deposition system 1 of the present embodiment with the foregoing configuration. Here, the first layer is formed from a substance 31b made of a low refractive index oxide material which is composed of SiO₂ containing approximately 2% of Fe. The second layer is formed from a substance 31a made of a high refractive index oxide material which is composed of Ta₂O₅ containing approximately 2% of Fe. By means of this thin-film deposition method, a multilayer optical thin film is formed by alternately laminating 32 layers based on the designed standard film thickness as shown in FIG. 3.

First, as in the first embodiment, using the substrate 22 on which an antireflection film 23 has been pre-formed on one face of the substrate 22, ion beam irradiation oriented toward the high refractive index oxide material 31a formed on the face opposite that one face is conducted for a specified time. By this means, the plate 10 arranged above the ion gun 8 is etched, and film deposition proceeds while Fe metal oxide is taken into the high refractive index oxide material 31a. Subsequently, at the point when film thickness of Ta₂O₅ reaches the designed standard film thickness of 115 nm, the shutter 6 is moved to the position above vapor deposition source 3 to cover it, thereby terminating film deposition of the first layer. Here, the ratio at which Fe is taken in is primarily dependent on the vapor deposition rate and ion gun power, and, in this instance, film deposition is conducted such that these are respectively 3 Å/sec and 600 W, resulting in Fe content of approximately 2%.

Furthermore, as in the first embodiment, irradiation is conducted with an ion beam for a specified time toward the low refractive index oxide material 31b. By this means, the plate 10 arranged above the ion gun 8 is etched, and film deposition proceeds while Fe metal oxide is taken into the low refractive index oxide material 31b. Subsequently, at the point when SiO₂ film thickness reaches the designed standard film thickness of 155 nm, the shutter 7 is moved to the position above vapor deposition source 4 to cover it, thereby terminating film deposition of the second layer. Here, the ratio at which Fe is taken in is primarily dependent on the vapor deposition rate and ion gun power, and, in this instance, film deposition is conducted such that these are respectively 7 Å/sec and 600 W, resulting in Fe content of approximately 2%.

Furthermore, by repeatedly conducting film deposition by the aforementioned film deposition process so as to reach the designed standard film thickness of each layer such as those shown in FIG. 3, a multilayer optical thin film 31 laminated in 32 layers is obtained.

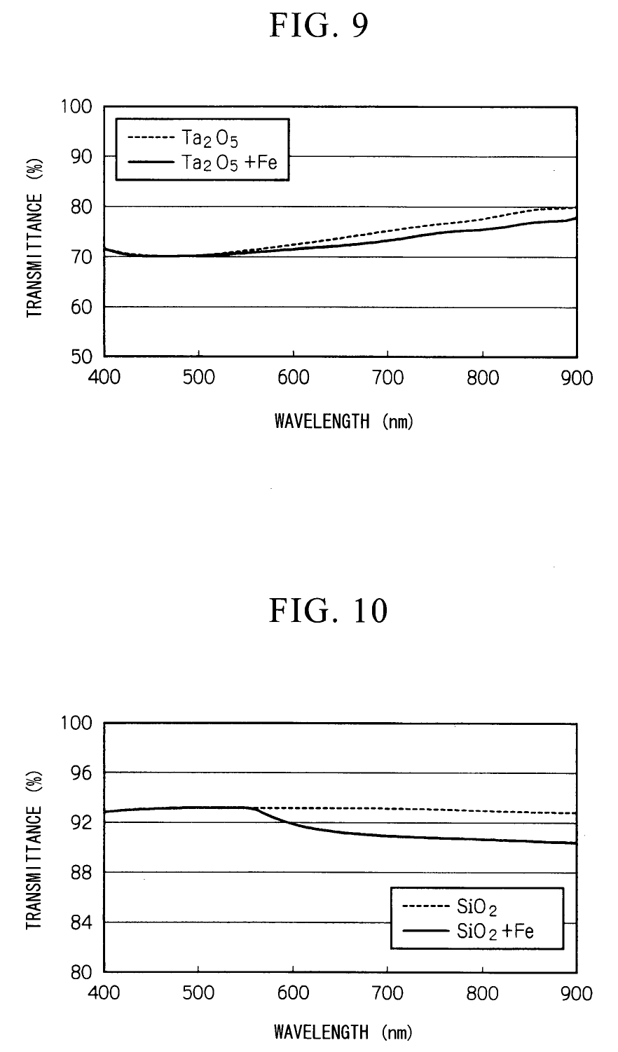

Here, as a comparison with this second embodiment, a spectrophotometer (U-4000, manufactured by Hitachi, Ltd.) was used to measure transmittance spectrum at wavelengths from 400 nm to 900 nm when a Ta₂O₅ monolayer refractive index layer was formed at λ/4 (λ=500 nm) in the cases where there was Fe content of approximately 2% on the substrate 22 and where there was no Fe content, and the results are shown in FIG. 9. As is clear from this figure, as a result of Fe absorption on the long wavelength side from the vicinity of 580 nm, compared to the case where λ/4 film deposition is conducted without Fe content, it is possible to obtain optical properties with the Ta₂O₅ monolayer refractive index layer containing Fe metal ions such that transmittance is attenuated by 1% at 630 nm and by 2% at 730 nm.

Furthermore, as a comparison with this second embodiment, a U-4000 spectrophotometer (manufactured by Hitachi, Ltd.) was used to measure transmittance spectrum at wavelengths from 400 nm to 900 nm when a SiO₂ monolayer refractive index layer was formed at λ/4 (λ=500 nm) in the cases where there was Fe content of approximately 2% on the substrate 22 and where there was no Fe content, and the results are shown in FIG. 10. As is clear from this figure, as a result of Fe absorption on the long wavelength side from the vicinity of 580 nm, compared to the case where λ/4 film deposition is conducted without Fe content, it is possible to obtain optical properties with the SiO₂ monolayer refractive index layer containing Fe metal ions such that transmittance is attenuated by 1.5% at 630 nm and by 3% at 730 nm.

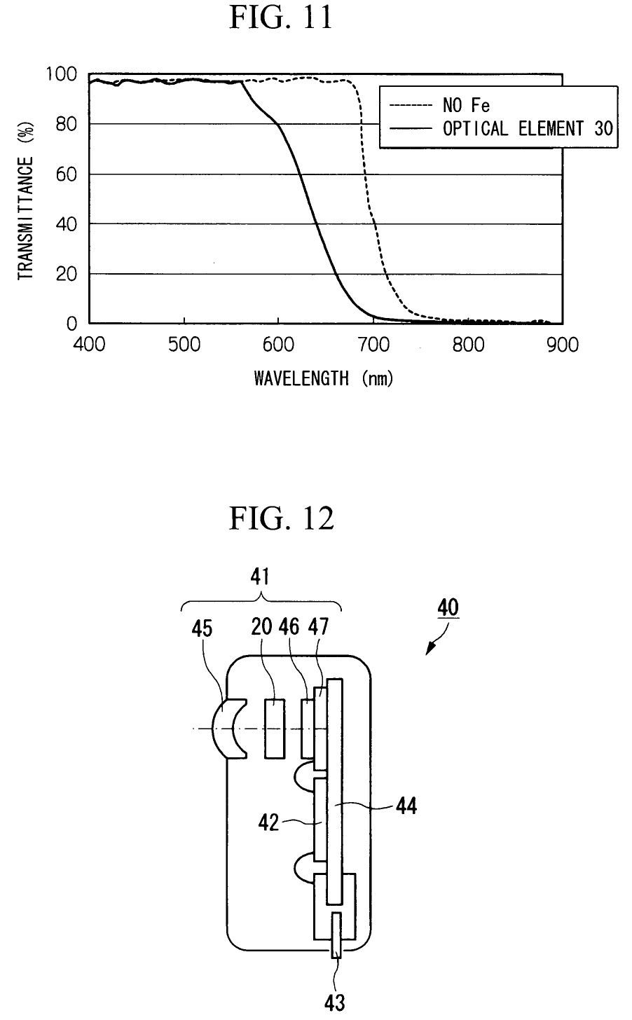

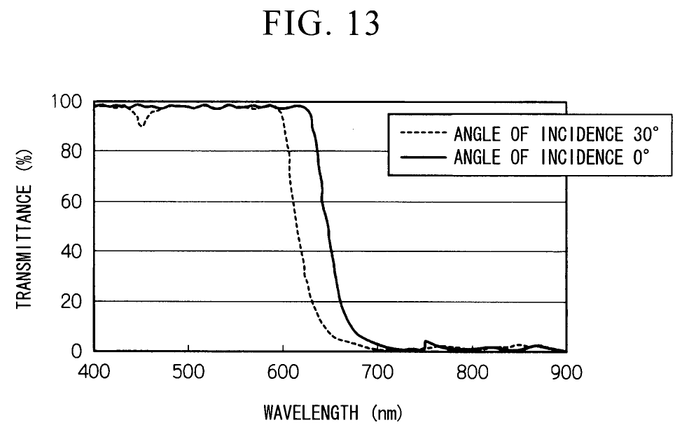

Additionally, the transmittance spectrum of the optical element 30 formed by the present embodiment was measured by a U-4000 spectrophotometer (manufactured by Hitachi, Ltd.) at wavelengths from 400 nm to 900 nm, and the results are shown in FIG. 11. When the optical thin film formed by Ta₂O₅ and SiO₂ without Fe content is compared with the optical element 30 which forms 32 layers of film such that film thicknesses like those shown in FIG. 3 are reached, this optical element 30 obtains transmittance that gradually attenuates from 580 nm to 730 nm as a result of the absorption of Fe metal ions on the long wavelength side from the vicinity of 580 nm. Specifically, the optical element 30 is capable of possessing transmittance of 58% at 630 nm and 0.5% at 730 nm.

According to the optical element 30 of the present embodiment, by utilizing the characteristic light absorption of the metal element Fe contained in the optical thin film 31 formed on the substrate 22, it is possible to cause transmission of necessary light such as visible light, and to absorb unnecessary light such as infrared rays.

Next, a description is given regarding a third embodiment of the present invention with reference to FIG. 12.

The description of the present embodiment concerns the case where the optical element 20 is used in a digital camera (optical equipment) 40.

The digital camera 40 is provided with an imaging module 41, processing circuit 42, memory card 43 which stores image data from the imaging module 41, and electrical substrate 44 which is electrically connected to these.

The imaging module 41 is provided with an imaging lens 45, optical element 20, microlens array 46, and solid-state image sensor 47. The optical images condensed by the imaging lens 45 are respectively condensed in each pixel of the solid-state image sensor 47 by the microlens array 46 with interposition of the optical element 20 on which is formed the optical thin film 21 that serves to transmit necessary light and absorb unnecessary light.

Next, a description is given of the method of use of the digital camera 40 of the present embodiment with the foregoing configuration.

The optical image received by the imaging lens 45 is condensed by the imaging lens 45, and is received by the optical element 20. Here, of the incoming light received by the imaging lens 45, the light in the non-transmission band of the optical thin film 21 of the optical element 20 is absorbed, while only the light in the transmission band is transmitted, and entered in the microlens array 46. At this point, absorbent glass has conventionally been used as the method of cutting off light by absorption, but by employing optical thin films 21 and 31 like those shown in the aforementioned first and second embodiments, this absorbent glass is rendered unnecessary.

The light received by the microlens array 46 is then respectively condensed into each pixel of the solid-state image sensor 47, and the optical image is converted into electric signals and becomes image data. This image data is displayed in a display device (not illustrated) such as a display by the processing circuit 42, and is stored in the memory card 43.

According to the digital camera 40 of the present embodiment, as transmittance spectrum hardly varies when light is received by the optical thin film containing a light absorbing metal element, the degree of freedom relative to the angle of incidence is expanded during optical design of digital cameras, compact modules and the like, enabling application to a wide range of optical equipment.

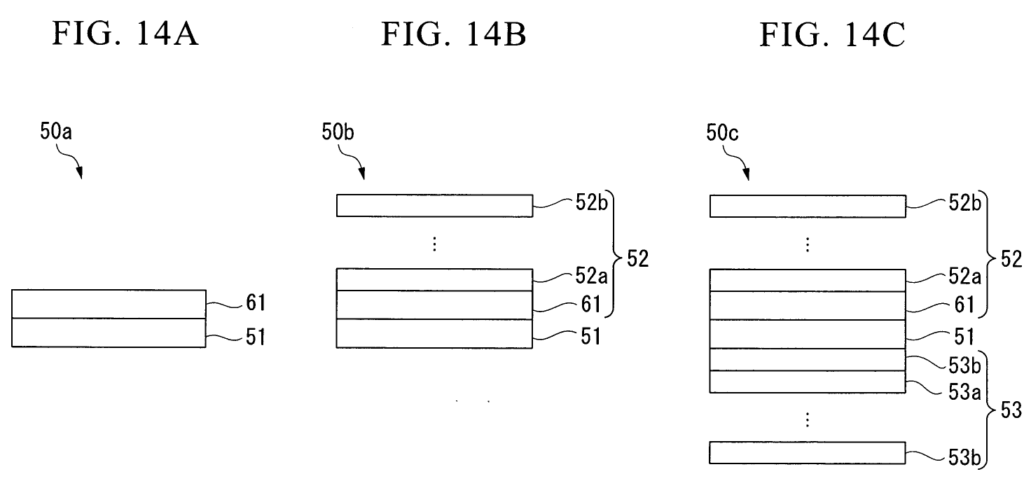

Next, a description is given of a fourth embodiment of the present invention with reference to FIG. 14 to FIG. 19. In each of the embodiments explained below, the same reference numbers are given to the components described in the foregoing embodiments, and description thereof is omitted.

The configuration of optical element 50c of the fourth embodiment differs from that of optical element 30 of the second embodiment in the following points. That is, optical element 50c pertaining to the fourth embodiment is provided with a quartz substrate 51 composed of quartz, and an optical thin film 52 which is a near-infrared ray cut-off filter is provided on one face of the quartz substrate 51. With respect to this optical thin film 52, the equal refraction index layer 61 which is the first layer from the quartz crystal has a refraction index approximately equal to that of the quartz substrate 51. Furthermore, an optical thin film 53 which is an ultraviolet ray cut-off filter is provided on the other face of the quartz substrate 51.

Next, using the optical element 50c of the present embodiment provided with the foregoing configuration, a description is given of the thin-film deposition method which forms the optical thin film 52 on one face of the quartz substrate 51, the thin-film deposition method which forms the optical thin film 53 on the other face of the quartz substrate 51, and the results of thin film evaluation pertaining to these.

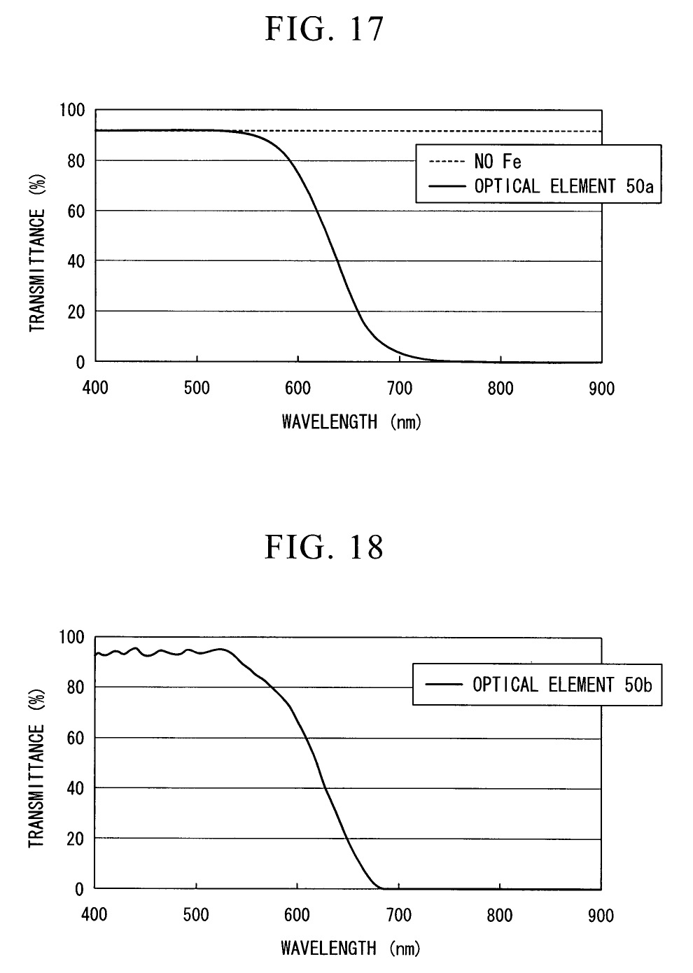

First, as in the optical element 50a shown in FIG. 14A, Nb₂O₅ which has a refraction index of 2.33 at a wavelength of 500 nm and SiO₂ which has a refraction index of 1.46 at a wavelength of 500 nm are mixed by the sputtering method at a ratio of 9:91 on one face of the quartz substrate 51. By this means, an oxide layer is obtained which has a refractive index approximately equal to that of the quartz substrate 51. This oxide layer becomes the aforementioned equal refraction index layer 61. In this instance, the respective oxide targets of Nb or Si are targets which respectively mix beforehand Fe and Nb or Si at a weight ratio of 2:98. This equal refraction index layer 61 which has a refractive index approximately equal to that of the quartz substrate 51 is formed so as to have a thickness of 5 μm. The refraction index of this optical element 50a is 1.55 at a wavelength of 500 nm. A U-4000 spectrophotometer (manufactured by Hitachi, Ltd.) was used to measure the transmittance spectrum of this optical element 50a from 400 nm to 900 nm, and the results are shown by the solid line in FIG. 17. Here, as a comparison with this fourth embodiment, a U-4000 spectrophotometer (manufactured by Hitachi, Ltd.) was used to measure the transmittance spectrum of an optical element wherein film deposition was conducted without including Fe metal ions in the oxide targets of both Nb and Si, and the results are shown by the dotted line in FIG. 17.

The optical element 50a of this FIG. 14A can be used instead of the glass type of infrared ray cut-off filters used in digital cameras. Moreover, the transmittance spectrum of the optical element 50a relative to an angle of incidence of 30° roughly overlaps with the solid line of FIG. 17, and hardly any variation in angle of incidence properties is observed.

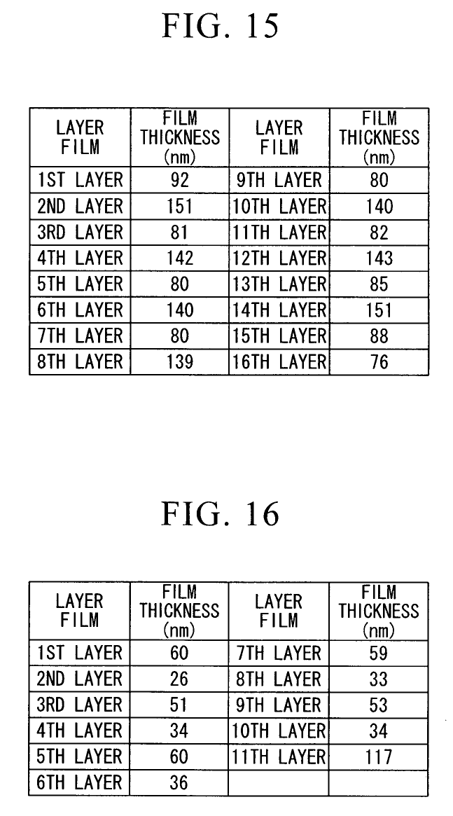

Additionally, as in the optical element 50b shown in FIG. 14B, an optical thin film 52 was formed by the sputtering method on top of the equal refractive index layer 61 by alternately conducting repetitive 16-layer lamination of Nb₂O₅ and SiO₂ without including Fe metal ions in the targets so that the designed standard film thickness was achieved for each layer like those shown in FIG. 15. In this instance, after Nb₂O₅ which is the high refractive index oxide layer 52a is formed on the equal refractive index layer 61, SiO₂ which is the low refractive index oxide layer 52b is formed in sequence. The transmittance spectrum of the optical element 50b at this time was measured by a U-4000 spectrophotometer (manufactured by Hitachi, Ltd.), and the results are shown in FIG. 18.

According to the optical element 50b shown in FIG. 14B, it is possible to obtain transmittance such that near-infrared rays are fully cut off at 700 nm to 900 nm. Furthermore, transmittance at this 50% position exhibits hardly any wavelength shift relative to the angle of incidence. Moreover, it is possible to greatly reduce the number of film layers.

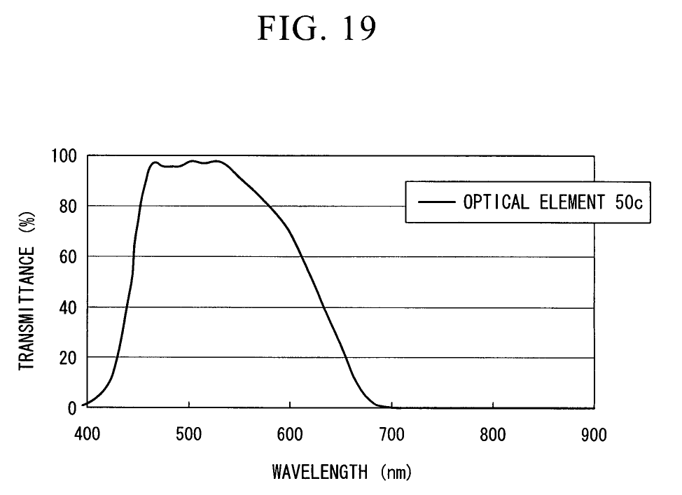

Furthermore, as in the optical element 50c shown in FIG. 14C, an optical thin film 53 was formed by the sputtering method on the other face of the quartz substrate 51 by conducting repetitive 11-layer lamination of SiO₂ and Nb₂O₅ so that designed standard film thickness was achieved for each layer like those shown in FIG. 16. In this instance, after SiO₂ which is the low refractive index oxide layer 53b is formed on the other face of the quartz substrate 51, Nb₂O₅ which is the high refractive index oxide layer 53a is formed in sequence, with the outermost layer being SiO₂ which is the low refractive index oxide layer 53b. Moreover, the respective oxide targets of the Nb or Si employed here were targets which respectively mix beforehand Ce and Nb or Si at a weight ratio of 5:95. The transmittance spectrum of the optical element 50c at this time was measured by a U-4000 spectrophotometer (manufactured by Hitachi, Ltd.), and the results are shown by the solid line in FIG. 19.

According to the optical element 50c shown in FIG. 14C, as transmittance spectrum approximating the sensitivity behavior of the human eye can be obtained, it is possible to simplify the CCD color balance adjustment of digital cameras. Furthermore, as the quartz substrate 51 possesses birefringent properties, it is possible to bond together a quartz substrate to which the optical thin film 52 that serves as the infrared ray cut-off filter is affixed and another quartz substrate, and to form an antireflection layer on the quartz substrates for use as an optical low-pass filter which is a key part of a digital camera.

The technical scope of the present invention is not limited by the foregoing embodiments, and it is possible to make a variety of modifications within a scope that does not deviate from the intent of the present invention.

For example, in the first and second embodiments, materials of the metal element Cu and material of the metal element Fe are used as the plate 10 between the ion gun 8 and gas induction tube 9. The plate 10 is not limited thereto, and it is also acceptable to use a plate of metallic material containing at least one element selected from among Au, Ag, Cr, Mn, Co and Ni, which have differing absorption wavelengths. Furthermore, it is also acceptable to conduct manufacture which causes inclusion of metal ions in the optical thin film 21 and 31 by conducting film deposition of metal oxide of Cu, Fe, Au, Ag, Cr, Mn, Co and Ni by a resistance heating or vapor deposition source (not illustrated) simultaneous with film deposition of the high refractive oxide material 21a and 31a and low refractive oxide material 21b and 31b.

Additionally, it is also acceptable to use material wherein metal ions of Cu, Fe, Au, Ag, Cr, Mn, Co and Ni are included in advance in the high refractive oxide material 21a and 31a and low refractive oxide material 21b and 31b. Moreover, film deposition is conducted by the ion assist vapor deposition method when manufacturing the optical thin film 21 and 31, but the method is not limited thereto, and the sputtering method, ion plating method, and ordinary vapor deposition method are also acceptable. With respect to the ion beam, in addition to Ar, N₂ or O₂ or a gas mixture of these are also acceptable. Furthermore, the optical thin films 21 and 31 have a metal element content of approximately 2%, but it is possible to make adjustments that increase the metal element amount by controlling the film deposition conditions of the ion gun 8 and the vapor deposition rate, and to reduce the number of film layers.

Additionally, during film deposition of the optical thin film 21 and 31, the optical thin film 21 and 31 on the substrate 22 is irradiated with an Ar ion beam using the ion gun 8 while introducing O₂ gas, but this may also be conducted using a plasma gun. Furthermore, the optical thin film 21 and 31 uses Ta₂O₅ and SiO₂, but one is not limited thereto, and it is also acceptable to use Nb₂O₅, TiO₂, ZrO₂, Al₂O₃, WO₃, SiO, HfO₂, and CeO₂. Or two or more of these substances may be mixed together. Furthermore, the high refractive index oxide material 21a and 31a is configured to contain oxide in all cases, but it is also acceptable if at least 1 layer of the high refractive index oxide material 21a and 31a is composed of material having oxide as its primary component, and has a refractive index higher than that of the low refractive index layer.

Moreover, in the third embodiment, the optical thin film 21 is formed on the optical element 20, but as the transmittance spectrum of this optical thin film 21 is hardly affected by variations in the angle of incidence, it is possible to form the optical thin film 21 on the imaging lens 45 where the angle of incidence varies. Consequently, it is also possible to render the optical element 20 unnecessary. Moreover, the digital camera 40 was described using the optical element 20, but similar results are obtainable even with the optical element 30 containing Fe metal ions.

Additionally, it is also acceptable to use the lens as the substrate 22, provide a CuO layer at the first layer, and make the optical thin film by alternately conducting 26-layer lamination of TiO₂ and SiO₂ thereon. In this case, as the manufacturing devices, sputtering devices are used which establish three sets of targets for the film raw materials. As sputtering targets, the three types of Cu, Ti and Si are established. As regards formation of the first layer, a CuO film is formed by the reactive sputtering method using a Cu target, and with induction of Ar gas and O₂ gas. Next, reactive sputtering is similarly conducted using a Ti target, and the TiO₂ film is formed. Furthermore, reactive sputtering is similarly conducted using a Si target, and the SiO₂ film is formed thereon. The optical thin film of the present invention can be obtained by alternately forming the TiO₂ film and SiO₂ film. The transmittance spectrum of the lens formed by this optical thin film is approximately equal to the values shown in FIG. 7. Moreover, in the case where this lens is used by incorporating it into optical equipment as an optical element, it comprehends light rays with angles of incidence from 0 degrees to 25 degrees relative to the lens surface, but it has been confirmed that this lens functions adequately as an infrared ray cut-off filter without causing any problems whatsoever in practical terms.

Additionally, it is also acceptable to make optical thin film which uses plate glass as the substrate 22, which provides a mixed layer (second layer) of CuO and WO₃ at the odd-numbered layers, and which alternately laminates this with MgF₂ (first layer) in 32 layers. In this case, a sputtering device is used which establishes two sets of targets for the film raw materials. As sputtering targets, the two types which are established are the target that mixes Cu and W at a weight ratio of 5:95, and the MgF₂ target. Moreover, with respect to formation of the first layer, a layer composed of W and Cu and O is formed using a mixed oxide target of Cu and W, with induction of Ar gas and O₂ gas. Next, MgF₂ film is formed using an MgF₂ target. The optical thin film of the present invention can then be obtained by alternately forming these layers. The transmittance spectrum of the lens formed by this optical thin film is approximately equal to the values shown in FIG. 7. Moreover, there is hardly any change in transmittance spectrum up to an angle of incidence of 30 degrees. As the second layer, instead of W, it is also acceptable to have a composition of Cu and O and at least one of Ta, Nb, Ti, Zr, Hf, Ce and La.

According to the present embodiment, as the wavelengths of the light absorbed by metal ions are fixed, by conducting film deposition with material containing metal ions of the wavelengths to be absorbed, there will be no variation in the absorbed wavelengths relative to changes in the angle of incidence of light. Accordingly, when at least one of Cu, Fe, Au, Ag, Cr, Mn, Co and Ni is intermixed with the optical thin film, variations in transmittance spectrum relative to changes in the angle of incidence becomes difficult. Specifically, in the glass type IR cut-off filter, CuO is added to phosphate glass so as to selectively absorb near-infrared rays. In this glass, the copper ions coordinated to numerous oxygen ions selectively absorb visible light and near-infrared rays on the long wavelength side from approximately 520 nm. Apart from Cu, metal ions such as Fe, Au, Ag, Cr, Mn, Co and Ni possess a similar characteristic of selectively absorbing specific light by coordination to numerous oxygen ions in glass. When broadly divided in three, Au, Ag and Mn selectively absorb visible light in wavelengths primarily from approximately 460 nm to 700 nm, Cu, Cr and Fe selectively absorb visible light in wavelengths primarily from approximately 520 nm to 700 nm, and Co and Ni selectively absorb visible light in wavelengths primarily from approximately 580 nm to 700 nm. In short, by conducting film deposition with material containing metal ions, it is possible to obtain an optical element on which is formed optical thin film constituting a filter that cuts off infrared rays with the coating type only wherein optical properties such as transmittance spectrum are independent. When the content of metal ions composed of Cu, Fe, Au, Ag, Cr, Mn, Co and Ni contained in the optical thin film is less than 0.5%, the effect is insufficient. Accordingly, it is preferable to have intermixture of metal ions content to be 1% or more, or 2% or more. When the content exceeds 30%, there is the possibility of causing a partial decline in transmittance of necessary light of the visible light region.

Additionally, with the present embodiment, by using oxide layers containing Cu, when Cu absorbs light in wavelengths from approximately 520 nm to 700 nm, transmittance spectrum is gradually attenuated from the visible light region to the near-infrared ray region. Incidentally, when oxide containing Cu is intermixed in layers whose primary component is SiO₂ or MgF₂ which are the low refractive index layers, the refractive index rises, and in optical thin film possessing low refractive index layers and high refractive index layers, the number of layers of optical thin film required for purposes of obtaining the necessary transmittance spectrum increases. Consequently, by intermixing an oxide containing Cu with at least one of Ta, Nb, Ti, W, Zr, Hf, Ce, La and Bi, or with a high refractive index layer composed of these oxides, film deposition is conducted on a substrate as an oxide layer containing Cu as the high refractive index layer.

As a result, by conducting lamination of high refractive index layers which are layers composed of Cu and O and at least one of Ta, Nb, Ti, W, Zr, Hf, Ce, La and Bi, and low refractive index layers whose primary component is SiO₂ or MgF₂, it is possible to form optical thin film having the desired transmittance spectrum. In addition, inclusion of an intermediate refractive index layer in the optical thin film, and inclusion of a high refractive index layer that does not contain Cu may be suitably conducted in the design. Moreover, when the content of metal ions composed of Cu contained in the optical thin film is less than 0.5%, the effect is insufficient, and when it exceeds 30%, there is the possibility that transmittance in the visible light region may be reduced.

When a first layer composed of material whose primary component is SiO₂ or MgF₂ is provided at the position which is farthest away from the substrate, as this layer is chemically stable, there is reduced occurrence of light scattering and the like at the layer surface even over long periods of time, and as it has superior mechanical strength, the layer surface is not readily scratched.

Additionally, in the present embodiment, it is possible to form optical thin film constituting an infrared ray cut-off filter by forming the aforementioned optical thin film on a substrate, and utilizing the absorption of Cu and the like. As the absorptive properties of Cu and the like are utilized, transmittance spectrum is hardly changed when light is received at varying angles. Utilizing this, it is possible to form a near-infrared ray cut-off filter on a lens surface by directly forming multilayer film on the face of a lens which has varying angles of incidence of incident light.

Additionally, in the present embodiment, it is possible to selectively absorb ultraviolet rays by using oxide layers containing at least one type of metal ion selected from among Pb, Ti, Bi, Ce and W in the optical thin film. Moreover, it is possible to selectively reflect ultraviolet rays by forming an ultraviolet ray cut-off filter of several tens of layers on the substrate. Furthermore, with respect to ultraviolet rays in the vicinity of 420 nm or less, in contrast to the sensitivity of the human eye which has almost no sensitivity in the vicinity of 420 nm, a CCD possesses sensitivity from the vicinity of 350 nm to the vicinity of 420 nm. Moreover, image processing was conducted so that the light received by the CCD is converted into electric signals to produce transmittance approximating the sensitivity behavior of the human eye, but it is possible to simplify the image processing which adjusts the color balance of blue color by adjusting the light rays that enter the CCD.

Additionally, in the present embodiment, an optical element provided with optical thin film that absorbs unnecessary light is made by setting the film thickness of the equal refractive index layer formed at the first layer from the substrate according to the required absorption amount. In particular, by conducting the setting so that near-infrared rays are absorbed, it is also possible to employ it as the near-infrared ray absorption glass used in digital cameras. Moreover, in contrast to the approximately 1 mm thickness of this near-infrared ray absorption glass, several μm is sufficient with the optical thin film, thereby enabling a reduction in thickness. Furthermore, optical thin film that forms antireflection film on top of the equal refraction index layer can improve the transmittance. Moreover, an optical element that forms multiple layers of optical thin film on an equal refraction index layer can be made to adjust the region where unnecessary light had been reflected and cut off by the interference of this optical thin film so that the unnecessary light is absorbed and cut off by the absorption of the equal refraction index layer, with the result that the number of film layers can be reduced. Furthermore, as transmittance varies relative to the angle of incidence when the unnecessary light is cut off by interference, but as transmittance hardly varies relative to the angle of incidence when the unnecessary light is cut off by absorption, this optical element also enables a reduction in angle properties.

Additionally, in the present embodiment, by forming the optical thin film of the near-infrared ray cut-off filter and ultraviolet ray cut-off filter on top of a quartz substrate, moiré prevention in digital cameras can be achieved, and it also becomes possible to simplify the color balance adjustment of the CCD. Moreover, an optical element which has a quartz substrate on which optical thin film is formed, or which bonds together multiple mated quartz substrates can also be employed as an optical low-pass filter used in digital cameras.

Additionally, in the present embodiment, the near-infrared ray absorption glass conventionally used in optical equipment can be omitted, whereby optical equipment such as digital cameras can be made more compact.

Additionally, according to the optical element and optical equipment of the present embodiment, when optical thin film is formed on the substrate, it becomes possible to form optical thin film which absorbs light, and to obtain optical elements and optical equipment having transmittance spectrum which is hardly affected by angle of incidence properties.

The foregoing has been a description of preferred embodiments of the present invention, but the present invention is not limited by these embodiments. Its configuration may undergo additions, omissions, substitutions, and other modifications within a scope that does not deviate from the intent of the present invention. The present invention is not limited by the descriptions stated above, and is only limited by the scope of the attached claims.

What is claimed is:

1. An optical element comprising a substrate and optical thin film formed in multiple layers on the surface of the pertinent substrate,
wherein said optical thin film is provided with low refractive index layers composed of material with a lower refractive index than that of said substrate,
and high refractive index layers of which at least 1 layer is composed of material whose primary component is oxide and which have a refractive index higher than that of said low refractive index layers,
and wherein at least 1 layer of said optical thin film composed of said low refractive index layers and said high refractive index layers contains at least one of metal ions selected from among Cu, Fe, Au, Ag, Cr, Mn, Co, and Ni.

2. An optical element comprising a substrate and optical thin film formed on the surface of the pertinent substrate,
wherein said optical thin film is provided with a first layer composed of material whose main component is SiO₂ or MgF₂,
and a second layer composed of Cu, O and at least one of Ta, Nb, Ti, W, Zr, Hf, Ce, La, and Bi,
and wherein said first layer is the layer formed at the position which is farthest away from said substrate among the layers configuring said optical thin film.

3. The optical element according to claims 1 or 2, wherein said optical thin film is a near-infrared ray cut-off filter which causes visible light to be transmitted, which absorbs a portion of the near-infrared rays, and which reflects near-infrared rays other than said absorbed near-infrared rays.

4. The optical element according to claims 1 or 2, wherein said optical thin film possesses transmittance having the function of an ultraviolet ray cut-off filter which absorbs a portion of the ultraviolet rays and which reflects ultraviolet rays other than said absorbed ultraviolet rays.

5. The optical element according to claims 1 or 2, wherein said optical thin film is provided at the first layer of said optical thin film from said substrate side with an equal refractive index layer which has a refractive index approximately equal to that of said substrate,
and wherein said equal refractive index layer contains metal ions of at least one type selected from among Cu, Fe, Au, Ag, Cr, Mn, Co, and Ni.

6. The optical element according to claims 1 or 2, wherein said substrate is quartz.

7. Optical equipment provided with the optical element according to claims 1 or 2.
